(19) United States
(12) Patent Application Publication
(10) Pub. No.: US 2007/0188783 A1
(43) Pub. Date: Aug. 16, 2007

(54) Image processing device, image processing method and image processing program storage medium

(75) Inventor: Noriko Hasegawa, Kanagawa (JP)

Correspondence Address: MORGAN LEWIS & BOCKIUS LLP, 1111 PENNSYLVANIA AVENUE NW, WASHINGTON, DC, 20004, US

(73) Assignee: Fuji Xerox Co., Ltd.

(21) Appl. No.: 11/639,220

(22) Filed: Dec. 15, 2006

(30) Foreign Application Priority Data
Feb. 15, 2006 (JP) 2006-038067

(51) Int. Cl. G03F 3/08

(52) U.S. Cl. 358/1.9; 358/521

(57) ABSTRACT

An image processing device includes a conversion section that converts an input image signal to an out put image signal within a color gamut of an output device by a predetermined conversion function, a storage section that stores a target value for a predetermined color and a predetermined standard gradation characteristic, and a determination section that determines the conversion function such that a gradation characteristic of the output image signal accords with at least a portion of the standard gradation characteristic. The conversion function is determined on the basis of the input signal, the target value for the predetermined color and the predetermined standard gradation characteristic.

### BACKGROUND

1. Technical Field

The present invention relates to an image processing device, an image processing method and an image processing program storage medium, and more particularly relates to an image processing device, image processing method and image processing program storage medium for performing color conversion processing on a color image signal in a case that possible color gamut of color image signals is differs between an input side and an output side.

2. Related Art

Devices for outputting color images include, for example, display devices such as CRTs, color LCDs and the like and printing devices such as printers and the like. With such output devices, ranges of colors that can be reproduced differ in accordance with differences in respective output methods and the like. Accordingly, in a case of, for example, printing an image prepared at a CRT with a printer, or the like, that means output is to be performed with the same image data for an output device which differs from an input device, some colors might not be reproduced. In such a case, the whole image with excellent image quality is tried to be reproduced by replacing and outputting the colors which could not be reproduced with colors that are considered closest to those colors. At such a time, mapping of colors to replace provided color image signals with colors signals within a possible color gamut of the output device (color mapping) is necessary.

### SUMMARY

One aspect of the present invention is an image processing device including a conversion section that converts an input image signal to an output image signal within a color gamut of an output device by a predetermined conversion function, a storage section that stores a target value for a predetermined color and a predetermined standard gradation characteristic, and a determination section that, on the basis of the input image signal, the target value for the predetermined color and the predetermined standard gradation characteristic, determines the conversion function such that a gradation characteristic of the output image signal accords with at least a portion of the standard gradation characteristic.

### BRIEF DESCRIPTION OF THE DRAWINGS

Exemplary embodiments of the present invention will be described in detail based on the following figures, wherein:

FIG. 1 is a block diagram showing an example of schematic structure of an image processing device relating to an exemplary embodiment of the present invention.

FIG. 2 is a block diagram showing an example of schematic structure of a color space signal conversion section of the image processing device.

FIG. 3 is a diagram for describing a gradation characteristic.

FIG. 4 is a diagram for describing the gradation characteristic.

FIG. 5 is a flowchart showing an example of a processing sequence of an image processing method relating to the exemplary embodiment of the present invention.

FIG. 6 is the flowchart showing the example of the processing sequence of the image processing method relating to the exemplary embodiment of the present invention.

FIG. 7 is a conceptual diagram showing an example of a color gamut.

FIG. 8 is a conceptual diagram of processing for conversion of a hue at a hue conversion section.

FIG. 9 is a diagram for describing a case in which a target point is outside a color gamut.

FIG. 10 is an explanatory diagram showing a specific example of color conversion processing for a case in which a brightness indicated by an intermediate image signal is higher than a cusp point brightness.

FIG. 11 is an explanatory diagram showing a specific example of color conversion processing for a case in which a brightness indicated by an intermediate image signal is lower than a cusp point brightness.

FIG. 12 is an explanatory diagram showing an example of non-linear compression mapping processing.

FIG. 13 is an explanatory diagram showing an example of color conversion processing for a case in which a point representing an intermediate image signal is located outside an intermediate color gamut.

### DESCRIPTION

Herebelow, an example of an exemplary embodiment of the present invention will be described in detail with reference to the drawings.

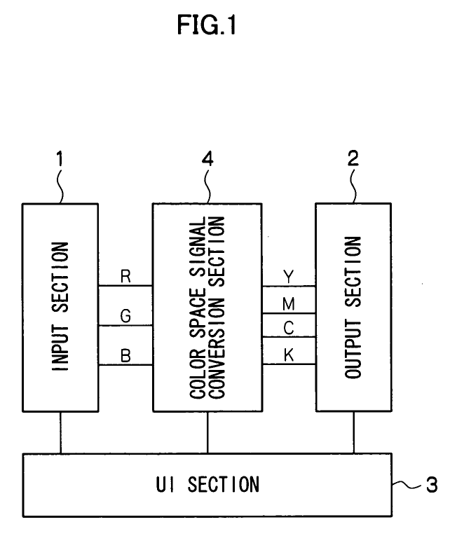

First, general structure of an image processing device will be described. FIG. 1 is a block diagram showing an example of schematic structure of the image processing device relating to an exemplary embodiment of the present invention. The image processing device to be described here is incorporated in an image output device, for example, a digital photocopier, a printer or the like, or is incorporated in a server device which is connected to such an image output device or incorporated in a computer (a driver device) which provides operational instructions to such an image output device. The image processing device which is employed thus is provided, as shown in the drawing, with an input section 1, an output section 2, a user interface section (below referred to as a UI section) 3 and a color space signal conversion section 4.

The input section 1 acquires input image signals. The input image signals may be, for example, color image signals in an RGB color space for display at a CRT or the like.

The output section 2 outputs image signals. The output image signals may be, for example, color image signals in a YMC color space or a YMCK color space, for printing with a printer or the like. For the present embodiment, a case in which the output image signals are color image signals in the YMCK color space will be described.

The UI section 3 implements various settings for the color space signal conversion section 4 in accordance with control by a user.

The color space signal conversion section 4 converts the input image signals acquired by the input section 1 to the output image signals that are outputted from the output section 2. Herein, at the color space signal conversion section 4, the conversion to the output image signals is performed after the input image signals are subjected to hue conversion processing, brightness conversion processing and compression mapping processing.

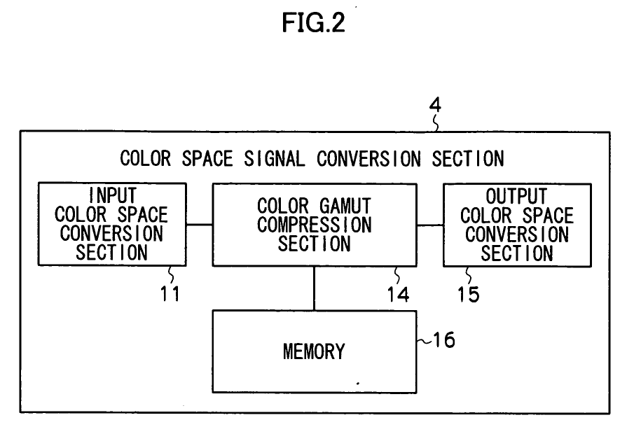

Now the color space signal conversion section 4 will be described in more detail. FIG. 2 is a block diagram showing schematic structure of the color space signal conversion section 4. As shown in FIG. 2, the color space signal conversion section 4 is provided with an input color space conversion section 11, a color gamut compression section 14, an output color space conversion section 15 and a memory 16.

When a color space of the input image signals differs from a below-mentioned color space, the input color space conversion section 11 carries out color space conversion processing into a color space that is to be employed as mentioned below. For example, in a case in which the input image signals are made according to the RGB color space whereas processing by the color gamut compression section 14 is to be performed in a color space which is not dependent on devices such as, for example the CIE-L*a*b* color space, the input color space conversion section 11 performs a conversion from the RGB color space into the L*a*b* color space. For the present embodiment, a case in which the CIE-L*a*b* color space is employed as the device-independent color space will be described, but this is not a limitation. Another device-independent color space, such as Jch or the like, can be employed.

When the input image signals are made according to the device-independent color space, there is no need for processing by the input color space conversion section 11 and, therefore, the input color space conversion section 11 can be omitted.

The color gamut compression section 14 temporarily converts the input image signals that are transmitted from the input color space conversion section 11 to intermediate image signals in accordance with a standard gradation characteristic or the like, which will be described more specifically later. Then, the color gamut compression section 14 converts the intermediate image signals to output image signals which are dependent on an output side color gamut. The standard gradation characteristic may, for example, be fixed on the basis of a device gradation characteristic of an input device, may be fixed on the basis of a gradation characteristic of the output device, and may be fixed on the basis of both.

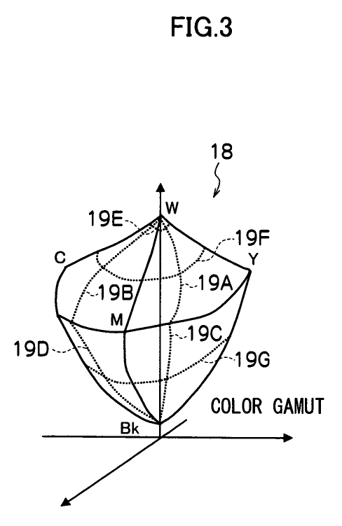

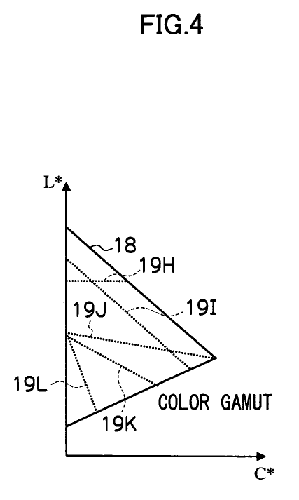

An example of a gradation characteristic includes loci joining arbitrary pairs of points on an edge of a color gamut 18, as shown by, for example, the dotted lines in FIG. 3. As these loci, there are loci 19A and 19B, from a white point W to points of maximum saturation on the edge of the color gamut 18, loci 19C and 19D, from a black point Bk to points of maximum saturation on the edge of the color gamut 18, hue-direction loci 19E, 19F and 19G, and so forth. Moreover, in addition to loci on the gamut edge as shown in FIG. 3, there are loci 19H, 191, 19J, 19K, 19L and so forth inside the color gamut 18, as shown in FIG. 4. Further, the gradation characteristic may be represented by color differences rather than loci.

In a case in which a color space of the output image signals differs from the color space that is employed in the image output device at the output side, the output color space conversion section 15 performs color space conversion processing into the color space that is employed in the image output device. For example, if the image output device is a printer or the like, the image output device will most likely handle image signals in the YMC color space or the YMCK color space. In such a case, the output color space conversion section 15 performs the color space conversion processing from the device-independent color space, for example, the CIE-L*a*b* color space, to the YMC color space or YMCK color space. Obviously, the device-independent color space signals might be outputted as is. In such a case, the processing of the output color space conversion section 15 is not necessary, and therefore the image signal processing device may be structured without the output color space conversion section 15.

The memory 16 stores various coefficients that the color gamut compression section 14 utilizes, such as conversion coefficients and the like, standard gradation characteristic data representing the standard gradation characteristic, a processing program, which will be described later, and the like.

It is conceivable that these sections 11 to 16 will be provided at, for example, an image output device, a server device or a driver device, and will be respectively realized by the execution of a predetermined program by a computer which is structured with a combination of a CPU (central processing unit), ROM (read-only memory), RAM (random access memory), and so forth.

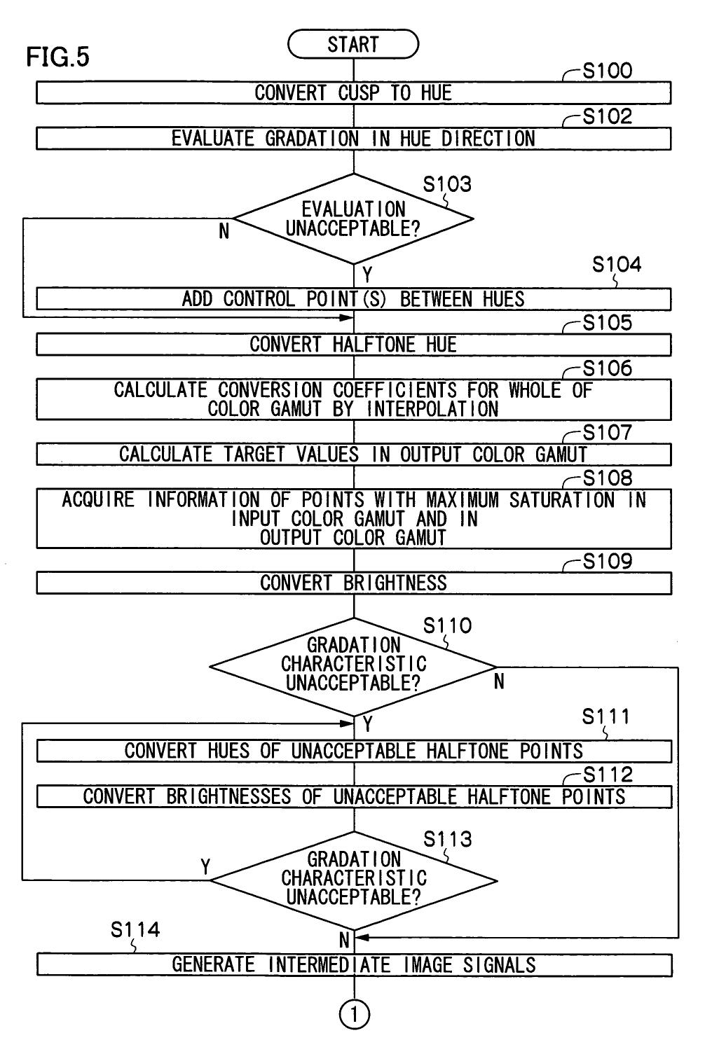

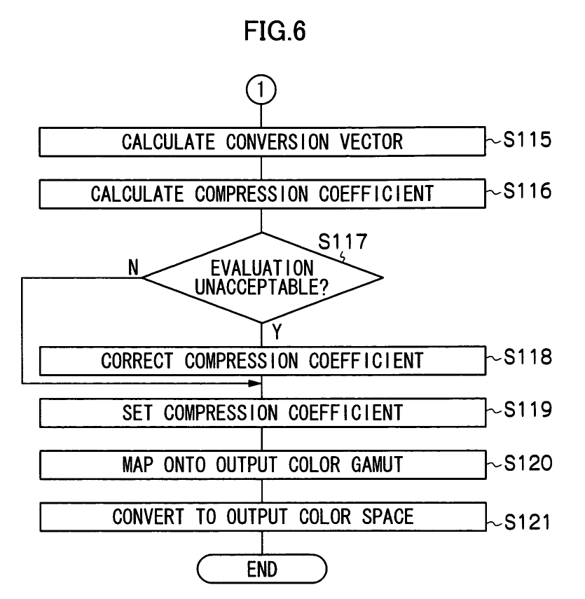

Next, an image processing sequence when input image signals are converted to output image signals at an image processing device structured as described above, namely an image processing method, will be described. FIGS. 5 and 6 are flowcharts showing an example of a processing sequence of the image processing method relating to the exemplary embodiment of the present invention.

When conversion processing of a color image signal is to be performed, first, an input side color gamut and an output side color gamut are calculated and stored in the memory 16 in advance. At this time, a color gamut according to a device-independent color space, for example, the CIE-L*a*b* color space, may also be calculated.

Note that in the following descriptions internal processing is being performed in the CIE-L*a*b* color space.

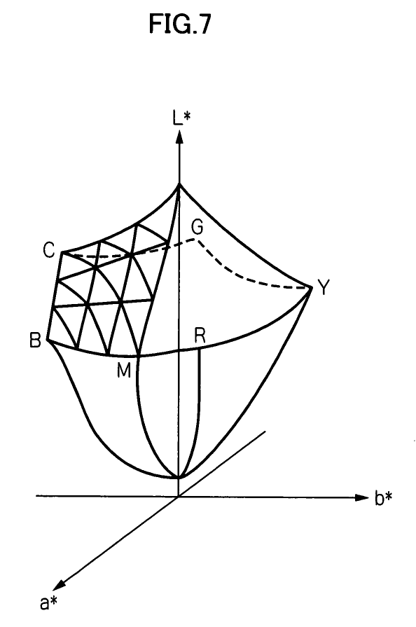

FIG. 7 is a conceptual diagram showing an example of a color gamut. In general, a color gamut is not regular but has a complex three-dimensional form, as is shown in FIG. 7. The inside of the solid shown in FIG. 7 is a region for which color reproduction is possible, and the outside of the solid is a region at which color reproduction is not possible. Accordingly, in order to calculate the color gamut, information (gamut edge information) of a surface (an outer border surface) which represents a boundary between the region for which color reproduction is possible and the region for which color reproduction is not possible is calculated in advance. As mentioned above, since the shape of this outer border surface is not regular, the outer border surface may be expressed by being divided into polygons such as, for example, triangles or the like. In FIG. 7, only a portion of the outer border surface is shown divided into triangular shapes, but such division can be performed over the whole of the outer border surface.

Color gamut data representing the input side color gamut and the output side color gamut which have been calculated is stored in the memory 16.

Then, each of points (CUSP) with maximum saturations of respective predetermined colors such as, for example, prime colors (e.g., R, G, B, Y, M and C), is converted to a hue of a pre-specified target value for each prime color (S101). The predetermined specified colors may be set to, in addition to the prime colors, for example, intermediate colors, arbitrary colors for which color reproduction is not expected to be the same at plural output devices, and colors specified by a user. The arbitrary colors for which color reproduction is not expected to be the same at the plural output devices are preferably specified colors available at, for example, vicinities of the prime colors in the color gamut of the output device. Further, if there is another target value for a hue in a vicinity of a target value for a hue of a color specified by a user, the target value of the color specified by the user may be given priority.

The target values are held at the memory 16 in advance in association with a color reproduction objective. Herein, the color reproduction objective may be designated by the user from the UI section 3. The color reproduction objective may be, for example, color reproduction which is close to a monitor. In such a case, values determined by experimental comparison with the monitor can be utilized as target values. For example, plural color patches, in which gradation values of a certain prime color have been converted in various manners, are compared by visual observation with colors which are displayed at the monitor to serve as references, and color patches that are subjectively evaluated as matching the colors displayed at the monitor can serve as target values. Another color reproduction objective may be, for example, vivid color reproduction. In such a case, the target values can be set to values determined by evaluation tests of output samples. Further, the target values may be determined by coverage of the output color space of an output device. In such a case, colors in vicinities of the prime colors can be set as the target values, and can be represented by levels of pure primaries (color saturation ratios).

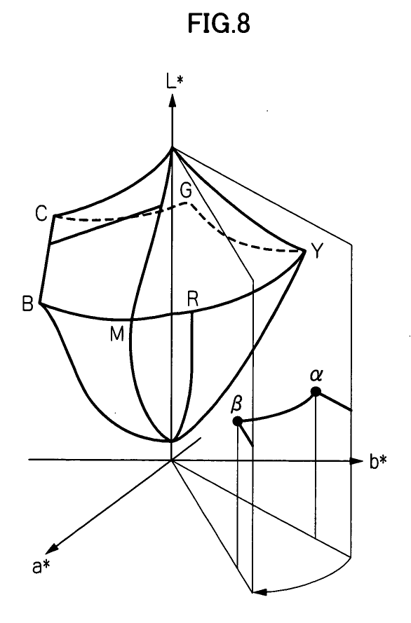

FIG. 8 is a conceptual diagram of hue conversion processing. In the CIE-L*a*b* color space, a conversion of hue means processing for a rotary movement around the L* axis. For example, the color of point α shown in FIG. 8 is rotated by a hue conversion section 12 and converted to the color of point β. Herein, rotation angles and rotation directions are determined in accordance with colors indicated by the input color image signals. For example, magentas (M) are moved significantly in a direction toward red (R). Further, blues (B) may be moved significantly in a direction toward cyan (C). In contrast, yellows (Y) may be substantially unchanged in hue.

Then, with lines linking cusp points of prime colors subsequent to the hue conversion serving as a hue-direction gradation characteristic, this hue-direction gradation characteristic is compared with a hue-direction standard gradation characteristic which has been specified in advance, and thus the hue-direction gradation characteristic is evaluated (S102). More specifically, it is judged whether or not there are locations at which the two gradation characteristics locally differ, that is, whether or not there are hue regions at which the gradation characteristic differs from the standard gradation characteristic. Herein, the standard gradation characteristic is held at the memory 16 in advance. The standard gradation characteristic can also be specified by a user.

Then, if it has been judged that there is a hue region at which the gradation characteristic differs (S103), control points, that is, colors with new hue angles are added within the hue region in order to make the gradation characteristic substantially match the standard gradation characteristic (S1104).

Next, hues of halftone image signals in the gradation characteristic of the prime colors, that is, hues between the L* axis and the cusp points with maximum saturation of the prime colors, are converted by a predetermined hue conversion function (S105). For this processing, a process described in Japanese Patent Application Laid-Open (JP-A) No. 2005-184601 may be employed. In the method described in this document, the conversion of hues is performed by a predetermined hue conversion function. According to this hue conversion function, the conversion of hues is such that a degree of hue conversion varies in accordance with saturations of the input image signals. The conversion of hues is performed such that hues in a high saturation region are greatly changed, whereas hues in a low saturation region are barely changed. This hue conversion function includes a variable which is a conversion coefficient that is specified in order to apply weightings according to the saturation to hue conversion degrees. More specifically, for example, an exponential function as shown in the following equation is employed.

Cout=Cin−Cdif×(Cdata/Cmax)^{Cnl1} (1)

In equation (1), Cout is a hue angle of an output image signal, Cin is a hue angle of an input image signal, Cdif is an amount of hue movement according to maximum saturation, Cdata is a saturation of the input image signal, and Cmax is a saturation of a point of maximum saturation. Meanwhile, Cnl1 is a conversion coefficient for weighting, being, for example, a non-linear coefficient for regulating non-linearity. Cnl1 has been set for each prime color and stored in the memory 16 in advance.

After halftone hues of the prime colors have been converted, conversion coefficients Cnl1 for colors between the prime colors are calculated by interpolation from the conversion coefficients of the prime colors (S106). Thus, conversion coefficients Cnl1 are set for the whole of the color gamut.

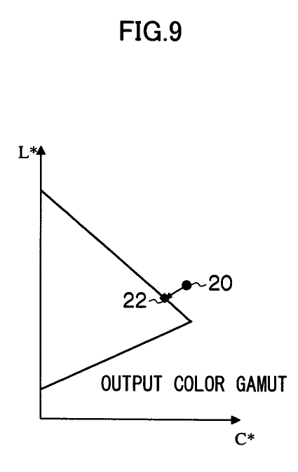

Next, of target points of the prime colors, target points that are outside the color gamut at the output side are converted to target points within the output side color gamut (S107). More specifically, as shown in FIG. 9, when an initial target point 20 is outside the color gamut at the output side, a point on the output side color gamut at which a color difference from this target point 20 is minimal is specified as a new target point 22.

Next, information representing positions of the cusp points with maximum saturation of respective hues, in the output side color gamut and the input side color gamut, is acquired (S108).

Then, brightnesses of halftone image signals of the gradation characteristic of the prime colors, that is, brightnesses of image signals between the L* axis and the cusp points with maximum saturation of the prime colors, are converted by a predetermined brightness conversion function (S109). For this processing, for example, a process described in the publication of JP-A No. 2005-184602 may be employed. In the method described in this document, the conversion of brightnesses is performed by a predetermined brightness conversion function. With this brightness conversion function, the conversion of brightnesses is such that a degree of brightness conversion varies in accordance with saturations of the input image signals. The conversion of brightnesses is carried out such that brightnesses in a high saturation region are greatly changed, whereas brightnesses in a low saturation region are barely changed. This brightness conversion function includes a variable which is a conversion coefficient that is specified in order to apply weightings to degrees of brightness conversion according to the saturation. More specifically, for example, an exponential function as shown in the following equation is employed.

Lout=Lin−Ldif×(Cdata/Cmax)^{Cnl2} (2)

In equation (2), Lout is a brightness value after conversion, Lin is a brightness value before conversion, Ldif is a brightness adjustment value, Cdata is a saturation of the input image signal, and Cmax is a saturation of a maximum saturation point of the input side color gamut. Meanwhile, Cnl2 is a conversion coefficient for weighting, being, for example, a non-linear coefficient for regulating non-linearity. Cnl2 has been set for each prime color and stored in the memory 16 in advance.

Next, the standard gradation characteristic of the prime colors specified in advance is compared with the gradation characteristic of the prime colors which has been hue-converted and brightness-converted by the processing described above. Hence, it is judged whether or not there is halftone data for which further hue and brightness conversion is necessary (S110). Herein, halftones has been converted so as to accord with the standard gradation characteristic at a low saturation side and so as to approach the target values of the prime colors at a high saturation side. Thus, it is judged whether or not the converted gradation characteristic of the prime colors is such a characteristic.

The standard gradation characteristic represents, for example, distances of loci in the L*a*b* color space from a predetermined point (for example, white) to the prime colors, or color differences, in two-dimensional graphs, and is stored in the memory 16 in advance.

First, at the time of the above judgment, the two-dimensional graphs representing the gradation characteristic of the prime colors that have been hue-converted and brightness-converted are calculated on the basis of distances from predetermined points of the loci of the prime colors to respective halftone points. These distances may be calculated for each of data points in the L*a*b* color space, and may be calculated for each of data points in the input side color space (for example, the RGB color space).

Then, the pre-specified standard gradation characteristic of the prime colors is compared with the converted gradation characteristic of the prime colors. When it is judged from results of the comparison that there are halftone points for which it is necessary to further convert the hue and brightness, the hues of these halftone points are re-converted (S111). For example, if a curvature of a locus of a prime color in the gradation characteristic needs to be larger (i.e., a curve is sharper), that is, if it is necessary to increase a number of gradations, then correction is performed such that a value of the hue conversion coefficient Cnl1 is made larger. On the other hand, if the curvature of a locus of a prime color in the gradation characteristic needs to be smaller (i.e., the curve is gentler), that is, if it is necessary to reduce the number of gradations, then correction is performed such that the value of the hue conversion coefficient Cnl1 is made smaller.

Next, the brightnesses of the halftone points for which it is necessary to convert the hue and brightness are re-converted (S112). For example, if the curvature of a locus of a prime color in the gradation characteristic needs to be larger (the curve is sharper), that is, if it is necessary to increase a number of gradations, then correction is performed such that a value of the brightness conversion coefficient Cnl2 is made larger. On the other hand, if the curvature of a locus of a prime color in the gradation characteristic needs to be smaller (the curve is gentler), that is, if it is necessary to reduce the number of gradations, then correction is performed such that the value of the brightness conversion coefficient Cnl2 is made smaller.

Then, similarly to S110, by comparison of the pre-specified standard gradation characteristic of the prime colors with the re-converted gradation characteristic of the prime colors, it is judged whether or not there are halftone points for which further hue and brightness conversion is necessary, and processing similar to that described above is repeated until there are no more such halftone points (S113). Thus, it is possible to make the gradation characteristic accord with the standard gradation characteristic with focusing on the low saturation side or the high brightness side, to which the human eye is attuned.

Thereafter, the image signals that are inputted are subjected to hue conversion and brightness conversion using the conversion coefficients Cnl1 and Cnl2 corresponding to the input image signals, and thus the intermediate image signals are generated (S114).

Hue and brightness conversions of a halftone gradation characteristic have been carried out in the L*a*b* color space in the above description, but may be performed in the input color space, for example, the RGB color space. Furthermore, the hues and brightnesses of the gradation characteristic have been converted so as to accord with the standard gradation characteristic but, in a case in which gradations can be smooth, changing the target values of the prime colors is also a possibility.

Next, conversion vectors for converting the intermediate image signals to output image signals are calculated (S115). More specifically, it is judged whether or not brightnesses of the intermediate image signals are higher than brightnesses of points (CUSPo) having maximum saturation in the output side color gamut.

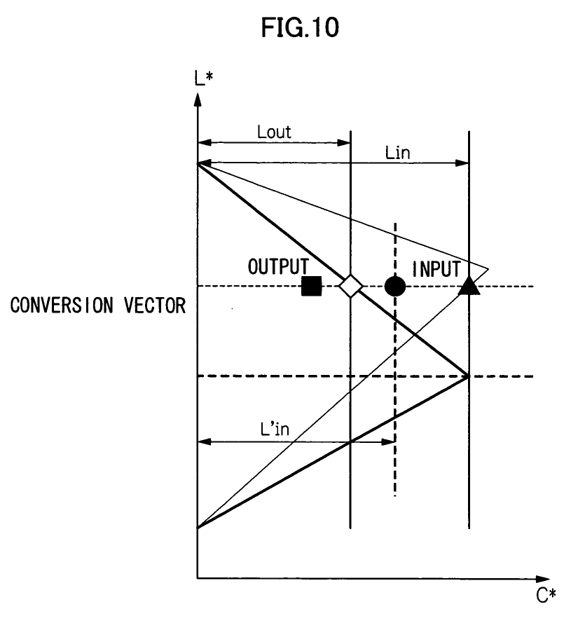

If the brightness of an intermediate image signal is higher than the brightnesses of a point CUSPo according to this judgment, the color gamut compression section 14 determines the direction of a conversion vector for this conversion processing (a conversion path) so as to conserve the brightness as is and perform conversion processing for saturation only. That is, as shown in FIG. 10, a straight line intersecting an axis of achromaticity (i.e., the L* axis) which also passes through a point representing the intermediate image signal (the circle in FIG. 10) is considered, and this straight line (which conserves brightness) is specified as the conversion vector. Because the brightness is conserved, the color gamut compression section 14 can perform color conversion such that high-brightness colors can be reproduced with suitably bright colors. Here, because the intermediate color gamut is specified and the brightness conversion processing is carried out therein, in comparison with a case in which color conversion is performed with brightness being conserved from an original input side color gamut, the colors become slightly darker while it is possible to perform color reproduction without whiteouts. Moreover, in comparison with a case in which brightness and saturation are both changed, it is possible to convert to colors with higher brightnesses. Therefore, an intermediate image signal in a high-brightness region can be converted to a color with high brightness, and color reproduction characteristics according to visual observation can be improved.

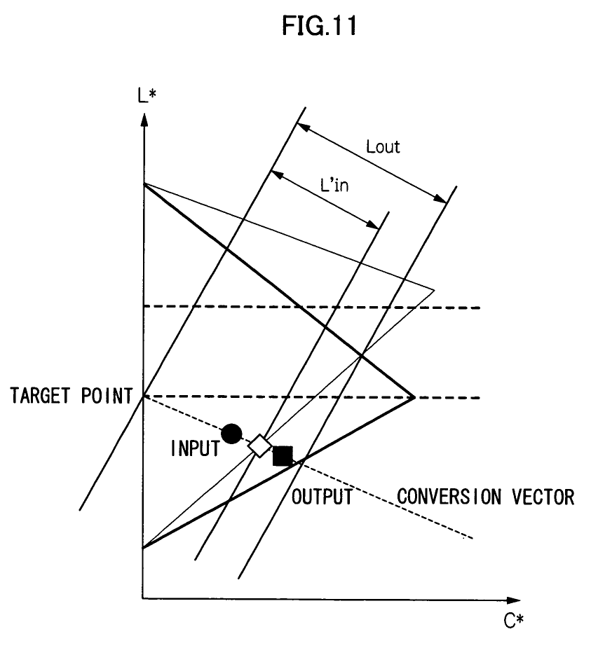

On the other hand, in a case in which the brightness of an intermediate image signal is lower than the brightness of a point CUSPo, as shown in FIG. 11, the color gamut compression section 14 takes, for example, an achromatic color (that is, a color on the L* axis) with a brightness the same as the brightness of the point CUSPo as an object point, and specifies a straight line joining the color of the intermediate image signal with this object point (i.e., in a direction in which a mixture characteristic of a colorant transforms) as the conversion vector. By performing conversion processing in accordance with this conversion vector, it is possible to convert low-brightness colors to colors which are apparently similar.

When a conversion vector is set, the color gamut compression section 14 specifies a compression coefficient (conversion coefficient) Cnl3 to be employed when obtaining an output image signal from the intermediate image signal, on the basis of a point on the intermediate color gamut edge and a point on the output color gamut edge (S116). This setting of compression coefficients Cnl3 and a later-described compression processing may employ, for example, a method described in the publication of JP-A No. 2005-191808. The compression coefficient Cnl3 is included as a variable in a non-linear function for conversion of the intermediate image signals to the output image signals by the color gamut compression section 14. Thus, the compression coefficient Cnl3 is a variable for specifying a compression ratio along the above-mentioned conversion vector. Accordingly, the compression coefficient Cnl3 is designated by the color gamut compression section 14 in accordance with a distance along the conversion vector between the object point (i.e., the achromatic point) and the point representing the intermediate image signal.

The compression coefficient Cnl3 is specified for each hue of the input image signals, and more specifically, for each hue of the intermediate image signals which are uniquely determined from the input image signals. That is, for example, as is shown in FIG. 9 of the above-mentioned JP-A No. 2005-191808 for linear compression (the diamond marks in that drawing), a reference coefficient (the square marks in that drawing), a coefficient 1 (the cross marks in that drawing) and a coefficient 2 (the triangle marks in that drawing), when hues are different, compression coefficients Cnl3 corresponding thereto are also different. The greater the compression coefficient, the stronger the non-linearity, as shown by coefficient 1 (the cross marks in that drawing), and the smaller the compression coefficient, the weaker the non-linearity, as shown by coefficient 2 (the triangle marks in that drawing). However, the compression coefficient Cnl3 is not necessarily required to be different for each hue, and the compression coefficients Cnl3 may be the same between different hues.

These compression coefficients Cnl3 may be registered in the memory 16 in advance for the prime colors only, and the color gamut compression section 14 can calculate hues therebetween by interpolation.

When the compression coefficients Cnl3 have been found, it is judged whether or not there are halftone points for which correction of the compression coefficient Cnl3 is required, by comparison of the gradation characteristic at the interior of each color gamut with the standard gradation characteristic (S117). This judgment can be performed by processing similar to that of S110.

Then, if there is a halftone point at which correction of the compression coefficient Cnl3 is required, the compression coefficient is corrected (S118). More specifically, if, for example, curvature of a locus of the gradation characteristic needs to be larger (i.e., a curve is sharper), that is, if it is necessary to increase a number of gradations, then correction is performed such that a value of the compression coefficient Cnl3 is made larger. On the other hand, if the curvature of a locus of the gradation characteristic needs to be smaller (i.e., the curve is gentler), that is, if it is necessary to reduce the number of gradations, then correction is performed such that the value of the compression coefficient Cnl3 is made smaller.

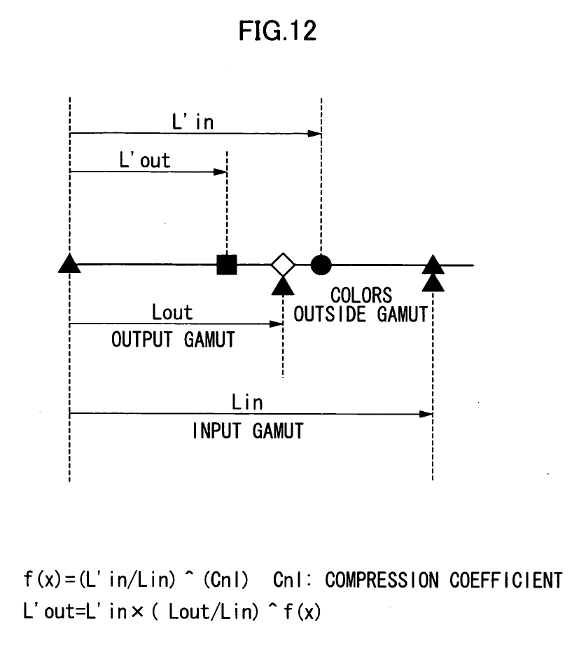

Then, compression coefficients Cnl3 corresponding to the intermediate image signals generated in S114 are calculated (S119), a non-linear function including the compression coefficient Cnl3 as a variable is employed, compression mapping processing is applied to the intermediate image signals, and thus output image signals are obtained from the intermediate image signals (S120). FIG. 12 is an explanatory view showing an example of non-linear compression mapping processing. As shown in FIG. 12, the color gamut compression section 14 employs the non-linear function of equations (3) and (4) shown below, based on distances Lin and Lout from the achromatic point on the conversion vector to respectively a point on the intermediate color gamut edge and a point on the output color gamut edge, and on a distance L′in from the achromatic point to the intermediate image signal, and the compression coefficient Cnl3 which is set in the memory 16 (shown as Cnl in FIG. 12). Thus, a distance L′out along the conversion vector from the achromatic point to the output image signal is found.

L′out=L′in×(Lout/Lin)^{f(x)} (3)

f(x)=(L′in/Lin)^{Cnl3} (4)

That is, at the color gamut compression section 14, in order to find the distance L′out of the output image signal along the conversion vector, a function is employed which is specified on the basis of positional information of the intermediate image signal in the intermediate color reproduction space, and the compression coefficient Cnl3. More specifically, at the time of compression mapping processing, an exponential function f(x) is used which provides the compression coefficient Cnl3 to serve as an exponential coefficient for a ratio, on the conversion path to the output image signal, between the distance L′in from the point relating to the positional information of the intermediate image signal to the achromatic point and the distance Lin from the outer border point of the intermediate color gamut to the achromatic point. Thus, the color gamut compression section 14 converts the intermediate image signals to the output image signals.

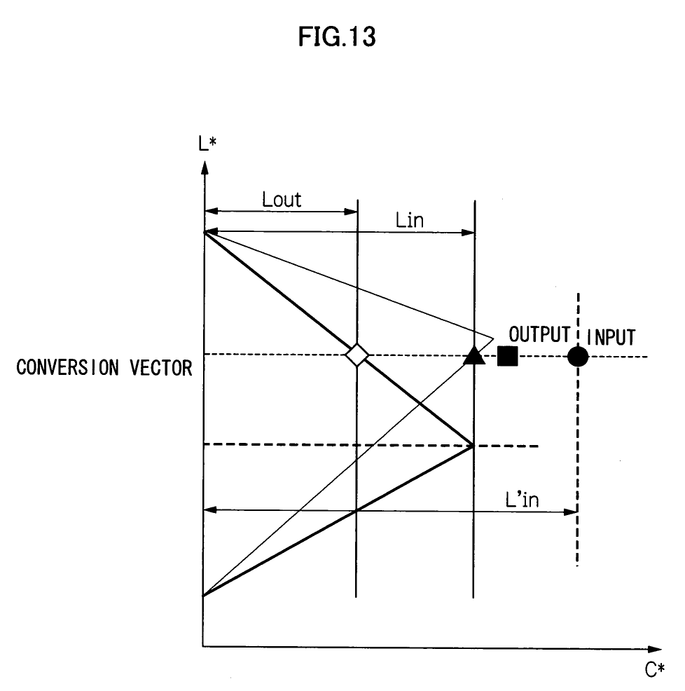

In a case in which the input color space is CIE-L*a*b* or the like, a notional input color gamut which is smaller than the CIE-L*a*b* color space may be specified, this notional input color gamut may be converted to the intermediate color gamut, and the intermediate color gamut may be compressed to the output color gamut. In such a case, some points representing intermediate image signals may be located outside the intermediate color gamut, that is, further to the outer side than outer border points of the intermediate color gamut. FIG. 13 is an explanatory view showing an example of color conversion processing in a case in which the point representing an intermediate image signal is located outside the intermediate color gamut. For the case shown in FIG. 13, it is possible for the color gamut compression section 14 to expand and utilize a conversion vector inside the intermediate color gamut that has been specified by the sequence described above, as a conversion vector for the color image signal outside the intermediate color gamut, and therewith convert the color image signal to an output image signal. Further, similarly, it is possible for the color gamut compression section 14 to expand and utilize a compression coefficient inside the intermediate color gamut that has been specified by the sequence described above, as a compression coefficient for the color image signal outside the intermediate color gamut, and perform non-linear compression therewith.

Thereafter, the output color space conversion section 15 performs a conversion, on the output image signals obtained by the conversion at the color gamut compression section 14, to the color space that the output side device requires (S121). For example, if the output side device employs color image signals in the YMCK color space, processing for conversion from the CE-L*a*b* color space to the YMCK color space may be performed. Obviously, if it will be acceptable to output the CIE-L*a*b* color space signals used for the internal processing as is, this conversion processing is not necessary. Thus, the processing ends.

Further, as described above, the respective conversion coefficients that have been determined are stored in the memory 16. If there is a prime color, a gradation characteristic or the like that is to be altered after the compression mapping, the conversion coefficients may be corrected in accordance with information of such alterations.

Further, a function correction section may be provided and configured such that when the hue-direction gradation characteristic of a prime color is compared with a hue-direction standard gradation characteristic set in advance and a locally differing hue region is found to exist, the function correction unit performs processing at the hue region so as to add colors with new hue angles in order to make the hue-direction gradation characteristic of the prime color substantially the same as the hue-direction standard gradation characteristic.

The function correction section can, for example, be provided at the color gamut compression section.

As described above, according to the image processing device and image processing method described for the present embodiment (including an image processing program for realizing the same), the conversion coefficients are determined, on the basis of the target values for hues and brightnesses of the prime colors and the like and the standard gradation characteristic, such that at least a portion of the gradation characteristic of the output image signals accords with the standard gradation characteristic. Thus, it is possible to cause the appearances of colors from different types of output device to substantially match.

In the present embodiment, the conversion coefficients are set such that at least a portion of the gradation characteristic matches up with the standard gradation characteristic when the input image signals are being converted to the intermediate image signals. However, rather than when converting the input image signals to the intermediate image signals, output image signals are provisionally generated in the color gamut of the output device by compression mapping, and a gradation characteristic of the output image signals may be evaluated so that at least a portion of this gradation characteristic is caused to match up with the standard gradation characteristic.

Further, an edge correction section may be provided that corrects the edge of a color gamut when an color image signal is converted to an output image signal. When, for example, a portion exists that varies locally on an edge line linking points of maximum saturation (CUSP) in a color gamut of a predetermined specified color, the edge correction section corrects the portion so as to make it smooth.

The edge correction section can, for example, be provided at the color gamut compression section.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The exemplary embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. An image processing device comprising:
a conversion section that converts an input image signal to an output image signal within a color gamut of an output device by a predetermined conversion function;
a storage section that stores a target value for a predetermined color and a predetermined standard gradation characteristic; and
a determination section that, on the basis of the input image signal, the target value for the predetermined color and the predetermined standard gradation characteristic, determines the conversion function such that a gradation characteristic of the output image signal accords with at least a portion of the standard gradation characteristic.

2. The image processing device of claim 1, wherein the determination section determines the conversion function such that the gradation characteristic for at least one of low saturation or high brightness accords with the standard gradation characteristic.

3. The image processing device of claim 1, wherein the gradation characteristic is represented by at least one of a color difference or a distance on a locus from a first predetermined position with low saturation to a second predetermined position within a predetermined color gamut.

4. The image processing device of claim 1, wherein the gradation characteristic is represented by at least one of a color difference or a distance on a locus in a hue direction from a first predetermined position to a second predetermined position within a predetermined color gamut.

5. The image processing device of claim 1, wherein the gradation characteristic comprises a gradation characteristic of a region with a brightness smaller than a brightness at a maximum saturation point in a predetermined color gamut, and is represented in a transformation direction of a mixing characteristic of a colorant.

6. The image processing device of claim 1, wherein the storage section stores, for each of color reproduction objectives, at least one of the target value for the predetermined color or standard gradation characteristic data relating to the predetermined standard gradation characteristic.

7. The image processing device of claim 1, wherein the predetermined color includes at least one of a saturated color of a prime color, an intermediate color, a color that is to be similarly reproduced at a plurality of output devices, or a color specified by a user.

8. The image processing device of claim 7, wherein the color that is to be similarly reproduced is set in a vicinity of a prime color in the color gamut of the output device.

9. The image processing device of claim 7, wherein, if there is another target value for a color in a vicinity of the target value for the color specified by a user, the color specified by a user is given priority.

10. The image processing device of claim 1, wherein the target value for the predetermined color is determined in accordance with an area ratio in the color space of the output device and is represented by a level of color purity, and the predetermined color is in a vicinity of a prime color.

11. The image processing device of claim 1, wherein, if the target value is outside the color gamut of the output device, a point on an outer border of the color gamut that is a point at which a color difference from the target value is minimal is set as the target value.

12. The image processing device of claim 1, further comprising an edge correction section that, if an edge line linking points of maximum saturation of a predetermined color gamut includes a portion that varies locally, performs correction so as to smoothen this portion.

13. The image processing device of claim 1, wherein the storage section stores the conversion function determined by the determination section, and the image processing device further comprises a function correction section that corrects the conversion function on the basis of information of alteration, if a characteristic of the predetermined color or the gradation characteristic is to be altered according to an outputted color.

14. The image processing device of claim 1, wherein the gradation characteristic is set on the basis of outer border information that represents an outer border of at least one of color gamuts of an input device and the output device.

15. An image processing method comprising:
converting an input image signal to an output image signal within a color gamut of an output device by a predetermined conversion function;
determining the conversion function such that a gradation characteristic of the output image signal accords with at least a portion of a standard gradation characteristic on the basis of the input image signal, a target value of a predetermined color and the predetermined standard gradation characteristic.

16. The image processing method of claim 15, wherein the conversion function is determined such that the gradation characteristic for at least one of low saturation or high brightness accords with the standard gradation characteristic.

17. The image processing method of claim 15, wherein the gradation characteristic is represented by at least one of a color difference or a distance on a locus from a first predetermined position with low saturation to a second predetermined position within a predetermined color gamut.

18. The image processing method of claim 15, wherein the gradation characteristic is represented by at least one of a color difference or a distance on a locus in a hue direction from a first predetermined position to a second predetermined position within a predetermined color gamut.

19. The image processing method of claim 15, wherein the gradation characteristic comprises a gradation characteristic of a region with a brightness smaller than a brightness at a maximum saturation point in a predetermined color gamut, and is represented in a transformation direction of a mixing characteristic of a colorant.

20. A storage medium storing an image processing program for execution by a computer of image processing, the image processing comprising:
converting an input image signal to an output image signal within a color gamut of an output device by a predetermined conversion function;
determining the conversion function such that a gradation characteristic of the output image signal accords with at least a portion of a standard gradation characteristic on the basis of the input image signal, a target value of a predetermined color stored in the storage section and the predetermined standard gradation characteristic stored in a storage section.
